(19) United States
(12) Patent Application Publication
(10) Pub. No.: US 2024/0412938 A1
(43) Pub. Date: Dec. 12, 2024

(54) SEMICONDUCTING COLD PHOTOCATHODE DEVICE USING ELECTRIC FIELD TO CONTROL THE ELECTRON AFFINITY

(71) Applicant: ATTOLIGHT AG, Lausanne (CH)

(72) Inventors: Nicolas Tappy, Fribourg (CH); Christian Monachon, Montreux (CH); Anna Fontcuberta i Morral, Morges (CH); Jean Berney, Lausanne (CH)

(21) Appl. No.: 18/393,329

(22) Filed: Dec. 21, 2023

Related U.S. Application Data
(60) Provisional application No. 63/434,882, filed on Dec. 22, 2022.

(51) Int. Cl. H01J 37/073; H01J 37/12; H01J 37/22; H01J 37/26

(52) U.S. Cl. CPC H01J 37/073; H01J 37/12; H01J 37/22; H01J 37/26; H01J 2237/06333

(57) ABSTRACT

An electron emitter comprises a tapered-shaped emission tip having a base face and an apex opposite the base face, the emission tip consisting essentially of semiconductor material, the semiconductor material being partially doped n-type and partially doped p-type, wherein the base face is doped one of n-type or p-type and the apex is doped opposite type of the base face and a p-n junction is thereby formed at a position between the base face and the apex.

### RELATED APPLICATIONS

This application claims priority from U.S. Provisional Application No. 63/434,882, filed Dec. 22, 2022, the disclosure of which is incorporated herein by reference in its entirety.

### BACKGROUND

### 1. Field

Embodiment disclosed include an electron-beam emitting device aimed for electron-microscopy (EM) and electron-beam assisted fabrication techniques, such as electron beam lithography (EBL) and Electron Beam Induced Deposition (EBID), and others.

### 2. Related Art

Electron emitters have been used in various electrical devices, from vacuum tubes, CRT (cathode-ray tube), and electron columns used in electron-based microscopes, such as scanning electron microscopes, transmission electron microscopes, etc. Most electron sources are made of tungsten. In some cases, they present as heated tungsten hairpins, where heat is used to extract electrons from the material (thermionic emission, thermionic emitters). In other cases, they present as sharp tungsten tips, where a combination of heat and electric field is used to extract electrons from the material (hot field emission, Schottky emitters). In those cases, the tungsten is covered with Zirconium Oxide (ZrO), a material that can enhance extraction efficiency by decreasing Tungsten's work function. Finally, in some cases emitters present as sharp tungsten tips where only electric field is used to extract electrons from the material (cold field emission, cold field emitters). All these sources operate well under continuous emission operation. However, various next-generation applications of electron beams in nanometrology and nanofabrication require the use of fast pulsed or modulated electron beams. Therefore, a new electron source is needed.

Applicant has previously employed the use of a pulsed laser to shine a beam on a tungsten tip in order to generate pulsed electron beam (photoemission, photocathode). However, such a method has an inherent limit to the yield of photoexcitation of metallic materials below 1 electron emitted per 10⁴ photons. Thus, a different solution is desired.

Photocathode materials are often used in light detection devices such as photomultiplier tubes, in which the active part of the device is maintained under vacuum and the electrons emitted from the surface are collected, giving a measurement of the number of impinging photons. These devices are typically made of metallic alloys or semiconductors, and to obtain efficient electron emission, a way to lower the electron affinity is needed and often consists of applying a certain coating on the material, such as Caesium.

In an effort to provide efficient, semiconductor-based, cold-field electron emitters, Shaw et al., proposed an emitter having a graded semiconductor coating over a substrate, such that the graded affinity structure promotes the attraction of electrons from the substrate to the surface via the bending of the conduction band of the graded affinity structure downward. This represents a way of lowering electron affinity that is unique to semiconductor materials. Further information can be found in U.S. Pat. No. 5,773,920.

Following the structure of photosensors described above, a semiconductor-based electron source has been developed, and is shown schematically in FIG. 1. A semiconductor plate 100 is coated in Caesium 101. The Caesium coating lowers the barrier for electron emission below the exciting photon energy, so as to increase the emission probability. In other words, lowering the so-called electron affinity, i.e., the energy required in order to extract an electron from it to the energy level of the vacuum, is always beneficial to photoelectron emission. Under this condition, a laser beam 110 illuminating the back of the plate causes photons to impact on the back of plate 110, to thereby cause electron emission from the front of the plate. Incidentally, within this disclosure reference to the “front” means the side from which electrons are emitted. Further information about this technology can be found in https://photoelectronsoul.com/en/technology.

In order for this structure to function properly, the front surface of the plate must be activated to negative electron affinity (NEA) so as to lower the vacuum level for electron extraction. This can be achieved by coating the front surface with caesium, as shown in FIG. 1 with coating 101. During operation, the caesium coating is degraded, thereby decreasing the quantum yield, which causes two problems. First, in order to keep the same electron beam current, the laser power must be constantly adjusted to account for the caesium degradation. This is explained in the 2022 publication of Continuous Test Results available from above cited website. Moreover, since the caesium coating is degraded during usage, the surface must be recoated in-situ, so as to avoid long downtime of the machine. To accomplish that an elaborate mechanism for caesium recoating must be included in the electron beam source, which makes the source more expensive, larger in size, more complex and hence prone to failures, and more difficult to maintain.

In view of the above, a new electron source that mitigates even just some of the shortcomings of the prior art would be desirable. Specifically, the new electron source should be capable of providing efficient photo-emission without resorting to coating such as ZrO or Caesium.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Disclosed embodiments provide solutions that overcome the drawbacks of the prior art emitters. Since tungsten-filament-based emitter are not well suited for non-continuous emission, disclosed embodiments provide emitters that can operate well even in rapid pulse mode. Conversely, since current semiconductor photoemitters require periodic surface reactivation, disclosed embodiments provide emitters that do not require any surface activation. Consequently, disclosed embodiments provide emitters that do not have the prior art problems of limited lifetime of the emitter, loss of efficiency over time, complexity of in-situ recoating, etc.

In order to avoid the need for caesium coating for surface activation, disclosed embodiments make use of the combined effects of p-type doping to shift the work function closer to vacuum level and a strong electric field applied at the semiconductor surface to control the electron affinity with precision. Applying a sufficient electric field to a semiconductor can influence significantly its electron affinity, and thereby its suitability for high photoelectron emission yield. This effect is specific to semiconductors. It originates from the fact that, unlike in a metal, electric field can penetrate inside a semiconductor and apply an electrostatic attraction or repulsion to electrons inside the material. This effect occurs at significant electric field strengths, typically 10 MV/m or higher. Generating the required electric field is achieved, at least in part, by a tip effect (also known as lightning rod effect), as will be explained further below. The application of temperature can be used as well to further control the electrical properties of the material, but the electron emission itself is stimulated by the application of laser light on the emitter surface. In this sense, the electron emitter is a cold photocathode device.

In disclosed embodiments the semiconductor emitter is formed into a sharp tip geometry, e.g., conical or pyramidal shape having a sharp tip, generally with apex radius less than 10 micron. In disclosed embodiments the apex area is doped p-type. Further embodiments will have the base area doped p-type as well, or doped n-type, with the p-n junction formed in between the base and apex. As noted by the inventors, while the p-type doping shifts the work function closer to vacuum level, it is insufficient for efficient emission of electrons. Thus, the addition of electric field is required. In the tip apex region, the strong electric field is enhanced by the sharp tip geometry (lightning rod effect), which assists in the electron emission efficiency by lowering the barrier (schottky effect) and marginally by tunneling. The strength of the electric field is configured for reductions of electron affinities in the chosen semiconducting materials, without reaching the onset of cold field emission. The extra energy required for emission is supplied by the laser photons. The emitted current follows the intensity of the laser light proportionally, so that any modulation in time or interruption of the electron beam can be realised by changing the laser intensity accordingly. Thus, with the disclosed embodiments, at least three knobs are provided to control the emission efficiency: the level of doping, the geometry of the tip, and the parameters of the laser beam.

Because the current generation of emitters is badly adapted to non-continuous emission, this device can successfully replace several alternative technologies in a less costly and more efficient manner.

### BRIEF DESCRIPTION OF THE DRAWINGS

Other aspects and features of the invention would be apparent from the detailed description, which is made with reference to the following drawings. It should be appreciated that the detailed description and the drawings provides various non-limiting examples of various embodiments of the invention, which is defined by the appended claims.

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a semiconductor emitter according to the prior art.

FIG. 2 illustrates a semiconductor electron emitter situated within a lens arrangement, according to an embodiment, while FIGS. 2A and 2B illustrate other embodiment of an electron emitter.

FIGS. 3A-3D illustrates a process for fabricating a semiconductor electron emitter according to an embodiment.

FIG. 4 is a schematic illustrating elements of an electron-based microscope, according to an embodiment;

FIG. 5 is a schematic illustrating elements of a parallel electron beam direct write lithography tool, according to an embodiment.

FIG. 5A illustrates an embodiment of multi-beam electron source.

### DETAILED DESCRIPTION

Embodiments of the innovative electron emitter will now be described with reference to the drawings. Different embodiments or their combinations may be used for different applications or to achieve different benefits. Depending on the outcome sought to be achieved, different features disclosed herein may be utilized partially or to their fullest, alone or in combination with other features, balancing advantages with requirements and constraints. Therefore, certain benefits will be highlighted with reference to different embodiments, but are not limited to the disclosed embodiments. That is, the features disclosed herein are not limited to the embodiment within which they are described, but may be “mixed and matched” with other features and incorporated in other embodiments.

Various embodiments disclosed below detail an innovative semiconductor-based, cold cathode, electron emitter. The emitter is designed to employ an electric field of a strength that, enhanced by the tip effect, causes adequate reduction of electron affinities for photoelectric electron emission, but without causing continuous emission. Rather, emission is initiated by the supply of photons from a light source, e.g. a laser. This state of operation is designated by the inventors “Field-Induced Negative Electron Affinity” (Field-Induced NEA). Thus, by controlling the operation of the laser emission, one can control the electron emission from the source in either continuous, modulated or pulsed modes. Notably, instead of the traditional blanking of the beam, the laser beam can simply be deflected or turned off, which can be done extremely fast in an abrupt fashion, such that the transition from on to off states of emission is a step function, as opposed to the traditional slower transition done by blanking of the electron beam.

According to the inventors, the design of an emitter based on Field-Induced NEA may follow certain guidelines, as follows.

The semiconductor material must allow Field-Induced NEA to be attained at relatively moderate fields to avoid significant tunneling through the vacuum barrier, however it must be strong enough to minimize space charge effects during electron pulse propagation in the vacuum. Extraction electric fields between 1 and 2 V/nm seem an appropriate starting point, as they are attainable in any Schottky cathode assembly and allow to reduce the emitter affinity between approximately 1 and 1.5 eV. Candidate materials must therefore exhibit electron affinity lower than 1.5 eV in excess of the bandgap in the p-doped variant.

The performance of lasers has sufficiently increased to consider that at any wavelength laser options will be available from sub-picosecond pulses up to Continuous-Wave (CW). However, keeping laser wavelength between 300 and 450 nm is desirable. Not only for keeping the cost of the driving light source lower, but also because the performances and ease of use of optical components decrease in the deeper UV range.

As indicated, the emitter is generally considered a cold cathode, since no heating is required for electron emission. However, at room temperature, electron emitters tend to accumulate impurities via adsorption from residual atmosphere. This induces a steady decrease in emitter current, requiring periodic heating up (with extraction voltage turned off) to provoke their desorption, a procedure called emitter flashing. The emitter should thus be able to operate at elevated temperatures to avoid this problem. If not possible, flash-heating for a short period at least should be possible. Aiming for an operation temperature of a few 100° C. above room temperature, e.g., operation temperature of 500° C. is advisable.

The advantages of a virtual electron source include decrease of space-charge effects, that would reduce brightness and image quality (continuous and pulsed operation) as well as time resolution (pulsed operation), and decrease of source size, associated with higher brightness and coherence of the beam. The emitter should thus reproduce the geometry of Schottky emitters close to the emitting area. This will ensure that in the environment of a cathode assembly, high fields up to several V/nm can be reached.

In some embodiments, the implementation of the emitter is designed for use in existing cathode assemblies, as a drop-in replacement for the current technology. This provides the fairest performance comparison with the existing technologies and allow technology transfer into existing instruments. Due to the geometry of electron emitters, that are mounted on tungsten wires, these embodiments require a back contact. For such embodiment, materials with bulk substrates readily available are beneficial over heteroepitaxial templates. Conversely, for embodiments not designed as a drop-in replacement, this constraint might be relaxed, both by moving away from the vertical device architecture or by engineering a heteroepitaxial stack on a substrate capable of injecting electrons from the back contact.

FIG. 2 illustrates an embodiment for a semiconductor electron emitter 200 positioned within a lens arrangement (generally electrostatic lenses) that here includes suppressor lens 220 and an extractor lens 230. The emitter is formed to have a main body 202, here shown as cylindrical but any shape suitable for mounting onto the source is acceptable, and a protruding emission tip 205, having a tapered shape, here shown generally as conical, but other shapes such as multi-facet (e.g., up to 100 facets) pyramidal can also be used. In embodiments, depending on the material used and the method used for fabrication of the emission tip, the exterior walls of the tip are at about 10°-20° angle ϕ with respect to the rotational axis of symmetry 204 passing through the apex and the base of the tip, and may generally be at 15° angle, depending on the methodology used to form the tip. To be clear, the sharper the tip is, or the smaller the angle ϕ, the stronger is the resulting tip effect, resulting in more efficient electron emission. Generally, the level of doping and the sharpness of the tip work in conjunction to improve the electron emission efficiency. Thus, theoretically, with all other variables held constant, a higher doping and sharper tip enhance emission efficiency. Importantly, with the disclosed embodiments, none of the surfaces of the emitter are coated with caesium.

The emitter 200 may be made of diamond, gallium nitride (GaN), silicon carbide (SiC), including 4H or 6H allotropic forms, or gallium phosphide (GaP). GaN may include the alloys InₓGa₁₋ₓN and AlₓGa₁₋ₓN and GaP may include the alloys InₓGa₁₋ₓP and AlₓGa₁₋ₓP or more complex alloys of Al, In, Ga, N, P. In embodiments, the entire main body 202 and emission tip 205 are made of semiconductor material doped p-type. The p-type doping level at the emission tip, especially at the apex of the emission tip, is designed to shift the work function of the semiconductor material sufficiently close to vacuum level to, in conjunction with the tip effect, enable ejection of electrons upon absorption of photons.

In other embodiments, the main body of the device 202 is doped n-type, while the base area 206 of the emission tip is doped n-type and only the apex region 208 of the emission tip is doped p-type. Effectively, a p-n junction is formed perpendicularly to the axis of symmetry 204 at a location between the base and the apex of the emission tip. With this structure the n-type region functions as the supply of electrons to the p-type region, allowing electrons to be photo-extracted from the emitter without charge loss. Generally, with metallic tips and other electron sources, spurious emissions reduce the intensity of the electron beam. Here, by having the main body doped n-type, it suppresses any spurious emission, even if the shaft is illuminated by the laser beam. Therefore, the emission is concentrated at the p-type apex, so that intensity is maintained.

In any of the embodiments, the body 202 and emission tip 205 are formed integrally as a monolithic structure, either by growth or by etching of the emission tip 205. For example, when constructing the emitter out of GaN, a starting point can be a substrate that is doped n-type, and incorporate magnesium (Mg) dopant during the crystal growth to form the p-type apex area 208 of the emission tip. In another example the entire emitter is made out of p-type diamond, and the main body 202 is coated with non-emitting coating 209 to avoid parasitic emission and force emission only from the tip apex. Conversely, the main body may be formed out of one semiconductor material and the tip made of different semiconductor material, wherein the main body can be doped p-type or n-type, and the tip doped p-type. For example, the main body can be fabricated out of an n-type semiconductor, while the tip is p-type diamond.

According to another example, the emitter is made of doped diamond. Diamond is beneficial for emitter fabrication since it presents high thermal conductivity, hole mobility and breakdown field. Diamond emitter can be fabricated using High-Pressure-High-Temperature (HPHT) and Chemical Vapor Deposition (CVD) processes, where phosphorus dopant can be used to form n-type doping and boron dopants can be incorporated during growth to obtain p-type conductivity. Unlike other embodiments where GaN is used, diamond is available as p-type substrates so that a p-n junction in the device architecture may or may not be used. That is, the entire emitter 200 may be fabricated out of a p-type diamond substrate, without the inclusion of n-type doping. Incidentally, annealing the diamond emission tip in ultra-high vacuum (UHV) at up to 900° C. helps get rid of oxygen and other contaminants.

In any of the embodiments, the emission generally occurs from the area illuminated by the laser beam. Consequently, the intensity and resolution of the electron beam is affected by the size of the laser beam. Therefore, by making the emitter 200 out of n-type doped material with just the apex doped p-type, even if the laser beam is larger than the apex and illuminates parts of the emitter outside of the apex, the emission will be limited to the apex area, since n-type material will not be emitting electrons due to laser illumination. Therefore, an emitter 200 having only the apex doped p-type may provide higher intensity and resolution of the emitted electron beam.

A back contact 203 is formed on the main body 202 enabling connection to base voltage V₀, which acts as a “virtual ground” or reference potential with respect to which all other voltages are measured. That virtual ground voltage may be different from earth/instrument chassis ground. The suppressor lens 220 is connected to negative Vsupp, while the extractor lens 230 is connected to positive Vext. These lenses are provided as but one example, and other lens arrangement may be used, e.g., existing lens arrangement used with filament-type emitter. The lenses are configured to form an electric field about the apex of the emission tip so as to induce lower electron affinity. In disclosed embodiments, the apex is doped p-type to obtain conduction band that is very close to vacuum level, and the tuning of the electron affinity can be done by proper tuning of the structure, the geometry and the level of doping of the n-type and p-type regions in the electron emitter. Also, in disclosed embodiment the apex is shaped to a diameter below 10 microns to enable reaching local electric fields above 10 MV/m to induce electron affinity of below, e.g., 1.5 eV, 1.0 eV or even down to below 0.0 eV. The latter case can be designated as Field-Induced NEA.

With the embodiment illustrated in FIG. 2, a laser source 211 is used to emit laser beam 210 directed at the apex of the tip with photon current Iₕᵥ. Whenever the photon stream from laser beam 210 hits the apex 208, the photons interaction with the material causes electron emission. Thus, by controlling the laser beam 210, one can control the emission of electrons. Since the laser beam can be pulsed at various rates and periods, the control of the laser can be used to turn emission on and off very sharply and precisely, thus eliminating the need for electron beam blanking mechanism. In fact, using on/off control of the laser beam can provide blanking speeds unattainable by conventional electron beam blanking apparatus and the transition between on and off conditions is more abrupt than possible with conventional beam blanking. Moreover, since the need for beam blanking apparatus is eliminated, the entire electron column can be made smaller, cheaper, more reliable, and more accurate.

FIG. 2A illustrates an embodiment similar to that of FIG. 2, except that the entire emitter 200 is made out of a p-type semiconductor material, without n-type and a p-n junction. Also, the contact is formed as a ring around a sidewall of the main body 202, such that the back surface 201 of the main body remains clear and exposed to laser illumination from the back surface. The callout in FIG. 2A is an SEM micrograph of a multi-facet tip fabricated in GaN with base radius of 20 microns.

The embodiments disclosed herein make use of various effects that enable highly controlled electron emission from the electron emitter. The effects include the use of doped semiconductor material to control the work function, and here p-type doping to actually lower the work function close to the vacuum level but high enough to avoid spontaneous or spurious emissions. The disclosed embodiments also utilize the tip effect to amplify the applied electric field and thereby enhance electron emission efficiency. The tip effect on the applied electrical field causes enhancement of the field at the tip to lower the electron affinity. The amount of doping and the shaping of the geometry of the tip is engineered to lower the work function and enhance the applied electric field, so that the application of photon energy generates high current of electron emission to levels several order of magnitude from what is attainable with filament emitters.

With the above description, an electron emitter is provided, comprising: a tapered-shaped emission tip 205 having a base face 206 and an apex 208 opposite the base face, the emission tip 205 consisting essentially of semiconductor material. In all embodiments, the apex is doped p-type, and in some embodiments the entire emission tip 205 is doped p-type. Alternatively, the semiconductor material might be partially doped n-type and partially doped p-type, wherein the base face is doped n-type and the apex is doped p-type, and a p-n junction 207 is thereby formed at a position between the base face and the apex. The p-n junction 207 defines a plan passing perpendicularly to an axis of symmetry 204 of the emission tip, the axis of symmetry passing through the apex and the center point of the base.

The electron emitter may further comprise a main body 202 formed of doped semiconductor acting as supply of electron for the emission tip, wherein the emission tip extends from one surface of the main body. An ohmic contact 203 is formed on a sidewall of the main body or on a second surface of the main body, opposite the one surface. The semiconductor material is selected from one of: doped diamond, gallium nitride (GaN) possibly alloyed with Aluminum (Al) and/or Indium (In), silicon carbide (SiC) including 4H or 6H allotropic forms, or gallium phosphide (GaP), also potentially alloyed with Al or In. In embodiments, the base face is doped n-type and the apex is doped p-type. In embodiments the emission tip is made of GaN wherein the apex is doped with magnesium (Mg), and in other embodiments the emission tip is made of diamond doped with boron to form p-type. In embodiments the emission tip is conical shaped, while in other embodiments the emission tip is pyramidal shaped, where the definition of pyramidal is extended from 4 to any number of edges, e.g. 6 in the case of GaN, based systems.

FIG. 2B illustrates another embodiment, wherein the emission tip 205 is attached to a filament 240, such as a tungsten filament. The emission tip 205 may be structured out of semiconductor material according to any of the embodiments disclosed herein. This embodiment is especially beneficial as a drop-in solution for systems designed for filament emitters. Mounting base 250 is an insulator, such as a ceramic insulator, having connectors 255 on one side and contact poles 245 on the other side. Electrical connection between the connectors 255 and contact poles 245 is done through the mounting base 250. The filament 240 is attached to the contact poles 245 and can receive electrical current therefrom. The electrical current may heat the filament and transfer heat energy to the emission tip 205. The energy applied to the emission tip generally would be below the spontaneous emission level, so that emission would occur only when photons from the laser beam 210 impinge on the apex of the emission tip 205. Beneficially, electrical field would also be applied to the emission tip via electrostatic lenses, such as suppressor lens 220 and an extractor lens 230 (see, FIG. 2).

In embodiments, two-photon lithography is used to fabricate one or multiple emitters on a single substrate. In the method, a substrate is coated with a Two-Photon Resist (TPR) and the objective of the lithography system is immersed in the TPR. In this sense, the TPR is used as fabrication material and resolution-enhancing immersion medium, owing to its refractive index around 1.5, similar to an immersion oil. The objective contacts the TPR and focuses the laser beam inside the TPR without passing through air, such that at each exposed position of the beam an elongated paraboloid volume called voxel is polymerized. By scanning the laser focus in the horizontal plane and moving the stage away from the objective, structures can be fabricated layer-by-layer from the liquid resist volume, similarly to stereolithography and 3D printing manufacturing techniques.

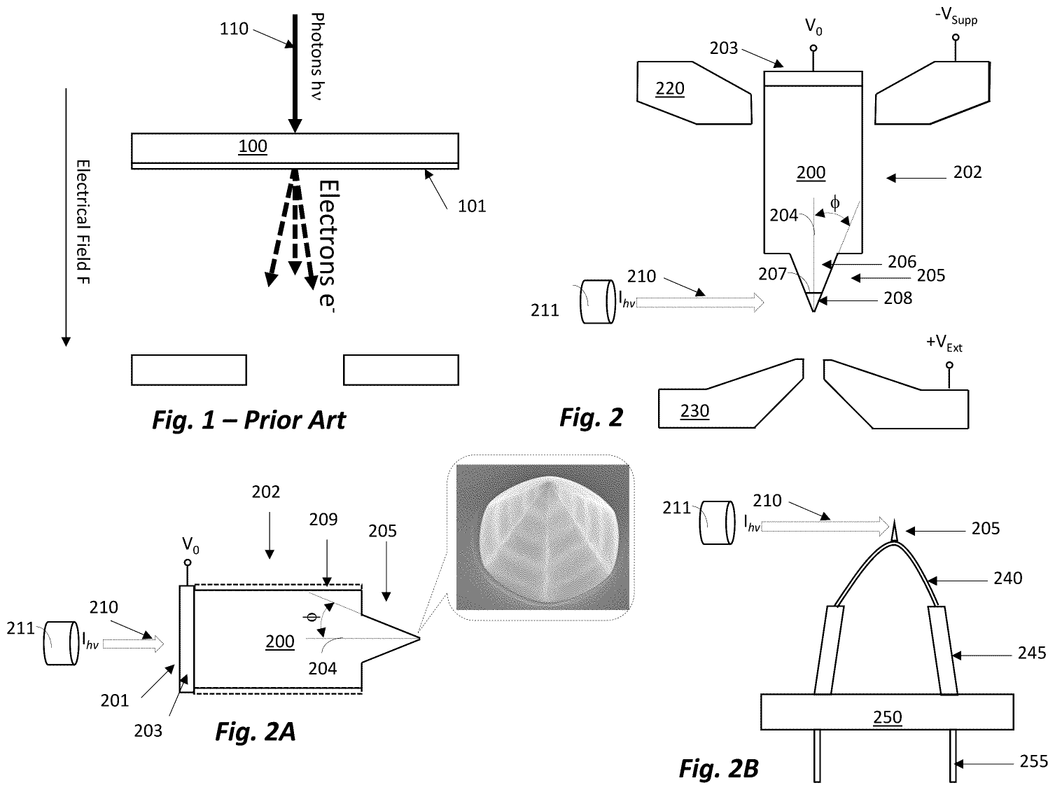

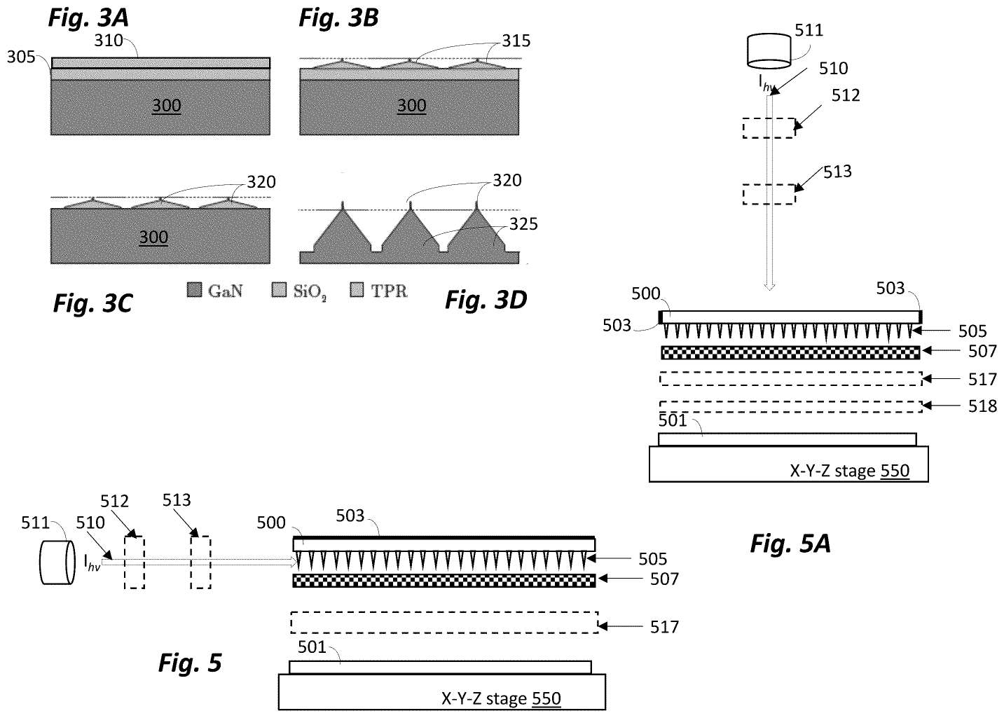

While a developed TPR is adequate as an etch mask, due to the high aspect ratio required to fabricate the emission tip, embodiments also utilize a two-mask approach: a TPR mask followed by a hard mask, e.g., an SiO₂ mask. FIGS. 3A-3D illustrate a process for forming an emission tip according to one embodiment. In FIGS. 3A-3D the dash-dotted lines show the top surface of a layer prior to the process step shown in the FIG. 1n this embodiment, three emission tips are formed simultaneously, but the same process can be used to form one or hundreds of tips simultaneously.

In FIG. 3A semiconductor substrate 300, e.g., GaN, is first coated with a hard mask layer 305, e.g., a layer of SiO₂, and a layer of TPR 310 is then formed over the hard mask layer 305. In FIG. 3B the TPR layer is exposed using a laser beam, and then developed to form TPR mask structures 315. The TPR mask structures 315 are used as masks to etch the hard-mask structures 320 in the hard mask layer, as illustrated in FIG. 3C. In FIG. 3D the hard-mask structures 320 are used to etch the emission tips 325 in the substrate 300. As shown in FIG. 3D, if the top region of the substrate is already doped p-type, the thickness of the hard mask 305 is designed so that at the end of etching of the emission tips 325, some amount of the hard-mask structure 320 remains. This ensure protection of the p-type apex. Conversely, the etch can be performed to generate a sharp apex regardless of consumption of the entire hard-mask structures 320, and thereafter the apex can be doped p-type, e.g., by diffusion or implant process. Also, the etching step of FIG. 3D can be done with reactive ion etching using the appropriate chemistry, e.g., using Cl2/Ar chemistry for a GaN substrate, oxygen plasma for diamond substrate, fluorine chemistry for SiC substrate, Cl2/Ar and for GaP substrate. An SiO2 hard mask can be used for any of these substrates, and can be etched using fluorine chemistry, e.g., C4F6.

By this disclosure, a method is provided for fabricating an electron emitter, comprising obtaining a semiconductor substrate doped n-type or p-type; forming an emission tip on one surface of the substrate; doping an apex area of the emission tip n-type or p-type, opposite doping of the substrate; and forming an ohmic contact on a surface of the substrate opposite the one surface. In the method, the amount of dopant and the shape of the tip are engineered to reach local electric fields above 10 MV/m (megavolt per meter) in the tip. In the method, the amount of dopant and the shape of the tip are engineered to lower the bandgap to be at a point below spontaneous emission, but generating emission upon absorbing photons from a laser source. In embodiment the fabrication starts with a doped semiconductor substrate, wherein upon one surface the electron emitter the tip is grown using, e.g., known epitaxial methods. Part way through the growth of the emission tip the dopant is switched from one of n-type and p-type dopant to the other of n-type or p-type dopant. Thereafter the substrate is cut to form the main body of the electron emitter and a contact is formed, e.g., by sputtering process, on the surface of the body opposite the emission tip, although the contact may be formed prior to cutting the substrate.

In other embodiments the fabrication starts with a doped semiconductor substrate, wherein upon one surface the electron emitter the tip is etched using, e.g., reactive ion etch methods. Thereafter, the apex of the tip is doped with a dopant opposite that of the substrate using, e.g., diffusion or ion implant methods. Alternatively, one surface of the substrate is first doped with a dopant of polarity opposite to the original dopant present in the substrate prior to processing, and the etching of the emission tip is performed to a depth surpassing a junction between the original dopant and the opposite dopant. The substrate is then cut to form the main body of the electron emitter and a contact is formed, e.g., by sputtering process, on the surface of the body opposite the emission tip. In embodiments the etch process is performed by forming on the substrate a layer of hard mask material, such as silicon dioxide, and forming over the hard mask layer a layer of a two-photon photoresist. Exposing the two-photon photoresist using immersion or other lithography process and then develop the two-photon photoresist to form a photoresist mask. Etching the hard mask layer through the photoresist mask to form a patterned hard mask, and thereafter etching the substrate through the hard mask to form at least one emission tip on masked surface of the substrate. The etching of the substrate is stopped prior to the consumption of the entire patterned hard mask material. In embodiment, the etching of the substrate is performed to form a plurality of emission tips on the substrate simultaneously.

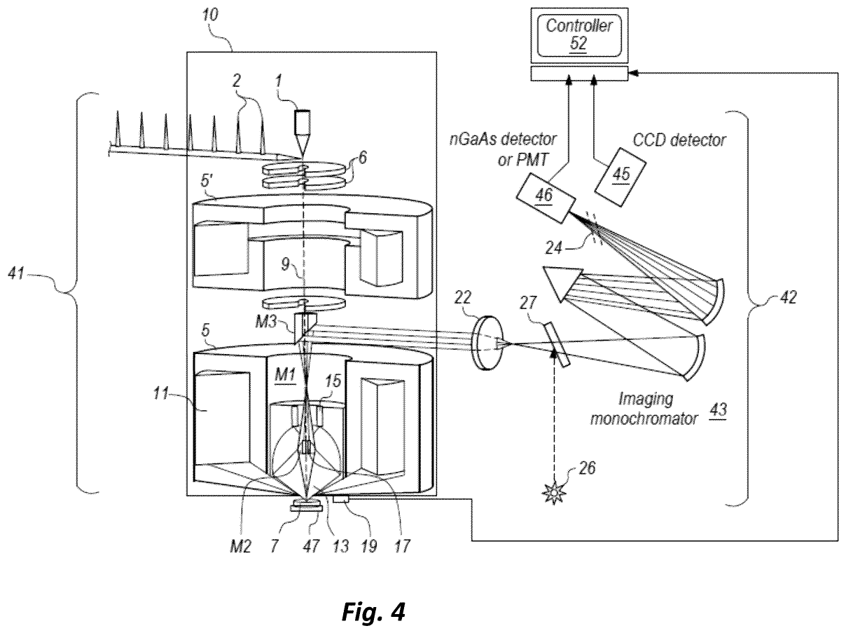

FIG. 4 schematically shows a lower portion of a microscope in cross-sectional view, according to an embodiment. As illustrated in FIG. 4, the microscope generally includes an electron column 41 that is housed within vacuum enclosure 10, and imaging elements 42, which are in atmospheric environment. The particular integrated microscope shown in FIG. 4 can generate an electron beam image, a light beam image, a cathodoluminescence (CL) image, and a CL spectroscopic image. However, the electron beam forming and scanning parts shown in FIG. 4 may be used in any other electron microscope, which may or may not include light optics. In the shown microscope, the imaged CL emissions can be correlated to the structure and quality of the sample's material at the nano-scale. The CL data can reveal material stress, impurities, crystallographic, and subsurface defects that are not visible using other imaging modes. Importantly, the CL imaging is a non-destructive method of inspecting a sample.

The electron column includes an electron emitter 1, such as a semiconductor electron source disclosed herein, that emits electrons upon exposure to laser beam (here indicated as pulses 2). The emitted electrons are made into electron beam 9 by the various particle-optics elements, such as electromagnetic lens 5′, electromagnetic objective 5, and aperture disks (sometimes referred to as stops) 6. Note that any of the aperture disks 6 may function as an electrostatic lens by application of potential thereto, such that aperture discs can function as suppressor lens and extractor lens. As noted, in FIG. 4, pulses 2 indicate that the electron emission from the semiconductor electron source 1 is done in pulses, but this is not necessarily so. For example, emission may be done continuously by application of a continuous laser beam or increase in the application of electrical field or heat.

The purpose of the magnetic field from lens 5 is to generate a converging electron beam 9 which can be focused on to the surface of the sample 7. In this example, the electron beam 9, which is generated by the electron emitter 1, propagates from the top of the figure downwards. The electron beam span may be modified by a condenser arrangement, such as a lens 5′, so that it can either diverge, be collimated, or converged.

The electromagnetic objective lens 5 may be rotationally symmetric along its optical axis, which essentially coincides with the path of the electron beam 9. The electromagnetic objective lens 5 is designed in such a way that the electron beam originating from the source 1 will be focused on to a focal plane. The position, and more specifically the height above the sample, of the focal plane can be adjusted by varying the intensity of the magnetic field flowing through the electromagnetic objective lens 5, although the lens is optimized to produce the smallest probe size when the focal plane is placed about 5 mm below the center of the electromagnetic objective lens 5.

The lens 5 has a hollow interior along its optical axis, so that the electron beam 9 can pass through. In the particular embodiment shown, the hollow part (passage or gap) is wide enough so that light emitted by or reflected from the sample 7 can also pass through without much obstruction. This may not be the case for electron microscopes that do not generate optical images. Since it is preferable to keep the output aperture 13 of the electromagnetic objective lens 5 as small as possible in order to keep good electron optical performance, it is preferable to build the system so that the working distance stays small.

As can be seen, a light-reflective objective is provided within the electromagnetic objective lens 5 for optical imaging the surface of the sample 7. In this example a Schwarzschild reflective objective is used. A Schwarzschild objective is a two mirror reflective objective, which is rotationally symmetric about the optical axis z, is aplanatic and infinity-corrected. In the context of geometrical optics, an objective is infinity-corrected if all light rays entering the objective parallel to the optical axis are focused onto the same focal point, forming a diffraction-limited spot, or conversely, all light rays emitted from the focal point and going through the objective form a bundle of light rays, or equivalently a collimated output beam, parallel to the optical axis. The electromagnetic objective lens 5 and the reflective objective may have the same focal plane.

As can be seen in FIG. 4, the reflective objective within the electromagnetic objective 5 comprises a first mirror M1, also referred to as the primary mirror, which in this example is spherical and concave, and a second mirror M2 also referred to as the secondary mirror, which in this example is spherical and convex. The diameter of the first mirror M1 is larger than the diameter of the second mirror M2. The first mirror M1 is located above the second mirror M2 and is arranged to reflect the light coming from the sample as a result of the electron beam 9 hitting the surface of the sample 7, and to direct the light towards the second mirror M2 placed between the sample and the first mirror M1. The second mirror M2 is arranged to redirect the light along the optical axis of the electromagnetic objective, and a third mirror, M3, which in this example is planar, is arranged to redirect the light beam 4 towards an output. In this example the third mirror M3 has a 45° angle with respect to the electron beam 9 axis and is used to redirect the light out of the vacuum enclosure 10. All the three mirrors M1, M2 and M3 have an aperture or opening along the electron beam path so that the electron beam is not obstructed.

The microscope shown in FIG. 4 also comprises a first electron beam deflector 17, referred to as a first deflector element or simply a first deflector 17, and a second electron beam deflector, referred to as a second deflector element or simply a second deflector 15. The first deflector 17 is located at least partly within the aperture of the second mirror M2, while the second deflector 15 is located at least partly within the aperture of the first mirror M1. In other words, the first deflector 17 is located radially inwards from the aperture of the second mirror M2 and at least partially axially coincident with that aperture, while the second deflector 15 is located radially inwards from the aperture of the first mirror M1 and at least partially axially coincident with that aperture. The deflectors 15, 17 are located so that they do not obstruct the propagation of the electron beam 9 or the reflected light beam.

The light reflected by mirror M3 is focused by lens 22 onto an imaging monochromator 43. In this example, two imagers are provided, a CCD camera 45 and a detector 46, such as an InGaAs or PMT detector. If mirror 24 is a half mirror, then both imagers can be operated simultaneously. Conversely, mirror 24 may be a flip mirror, enabling one imager at a time. With this arrangement, detector 46 can be used to detect light intensity of a specified wavelength, while CCD camera may be used to detect light intensity at several wavelengths simultaneously.

In order to generate a light image of the sample, light source 26 may be operated to generate a light beam that is reflected by flip mirror 27 onto the lens 22, and thence to mirror M3 towards the sample via mirrors M2 and M1, wherein reflected light would travel the reverse path into the CCD camera. In this mode of operation, the mirror arrangement comprising the three mirrors M1, M2 and M3 is used to direct light to the sample 7 from light source 26 and to collect the light reflected from the sample 7 and direct it towards the CCD detector 45.

In the embodiment of FIG. 4, an electron detector 19 is provided, to be able to detect secondary electrons emitted from the sample, or back scattered electrons reflected by the sample. The signal of this detector can be used to generate a scanning electron microscope (SEM) image. Also, in the embodiment of FIG. 4, the sample holder 47 may be in the form of a cryogenic stage, which keeps the sample at low temperatures thereby avoiding noisy light emissions.

With the above disclosure, an electron-based microscope is provided, comprising: a specimen holder, e.g., a stage; an electron emitter made of semiconductor material shaped to form a tip having an apex, the apex being doped p-type; a laser source directing a laser beam onto the apex to cause the electron emitter to emit electrons; electron optics configured to form an electron beam out of the electrons emitted from the electron emitter and direct the electron beam onto the specimen; and a sensor positioned to detect emissions from the specimen.

As semiconductor design rules approach single digit nanometer size, i.e., 10-nm node and beyond, a need for replacement lithography arises. One promising technology is electron-beam direct write and, more specifically, multiple parallel electron beam direct write. With such technology, multiple electron beams are energized in parallel to directly write the circuit design onto the resist. Thus, the entire process of making masks is bypassed. Several proposals have been made for a direct write tools that use a plurality of electron beams. For example, Esashi et al., have proposed a massively parallel electron beam direct write apparatus using active-matrix nanocrystalline-silicon electron emitter array. See, Microsystems & Nanoengineering (2015) 1, 15029; doi: 10.1038/micronano.2015.29. However, no system using doped semiconductor with tip effect has been proposed. Moreover, the blanking, or turning on/off of the beam remains a complex problem for such miniaturized devices.

FIG. 5 illustrates a direct write apparatus according to an embodiment. A substrate 500, e.g., a semiconductor substrate, have a plurality of electron emission tips 505 formed over one (front) surface thereof. The semiconductor substrate 500 may be doped one of n-type or p-type, and may be made of, e.g., doped silicon, doped diamond, gallium nitride (GaN), silicon carbide (SiC) including 4H or 6H allotropic forms, or gallium phosphide (GaP). Each of the electron emission tips 505 may be formed according to any of the embodiments disclosed herein and may be partially doped n-type and partially doped p-type, but the apex of each electron emission tip 505 is doped p-type. In this embodiment the ohmic contact 503 is formed over the other surface of the substrate 500, opposite the front surface having the electron emitters, or alternatively patterned around them. An electrostatic lens layer 507 is positioned in close proximity to the plurality of electron emitters, and may include a plurality of conditioning lenses, such that each of the conditioning lenses may include a suppressor lens, an extractor lens, an aperture lens, etc. The number of conditioning lenses equals the number of electron emitters, such that each conditioning lens impose electric field on one corresponding electron emitter.

A laser source 511 is used to generate laser beam 510, which can be split into a plurality of laser beams by optional beam splitter 512. Also, an optional laser-beam scanner 513, such as an electro-optic or acousto-optic laser beam scanner, can be included in the optical path, to aim each laser beam onto various electron emission tips 505, either from the side or from the back of each tip. Consequently the control of the laser beam(s) effectively acts as electron beam blocker. Finally, an optional beam forming and scanning layer 517 is provided to focus the multiple electron beams and scan the electron beams on the surface of workpiece 501, which is positioned on an X-Y-Z stage 550. The scanning layer 517 may include magnetic lenses, electrostatic lenses, or both electrostatic and magnetic lenses.

FIG. 5A illustrates an embodiment of multi-beam electron source, which may be used for applications such as, e.g., inspection microscope, direct write, etc. Much of the structure of this embodiment is the same as that shown in FIG. 5; therefore, the explanation will not be repeated. However, in this embodiment the laser beam is illuminating the electron emission tips 505 from the back of the substrate 500. Therefore, the contact 503 has been provided on the sidewall of the substrate. Conversely, it could be provided on the front or back of the substrate 500 so as to let the laser reach the emitters array while still providing an efficient electrical contact. In those case, patterned contacts are needed. Additionally, when the multi-beam electron source is used in microscope applications, an optional sensor layer 518 may be included, to detect secondary and back scattered electrons emitted from the workpiece 501.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

1. An electron emitter, comprising:
a tapered-shaped emission tip having a base face and an apex opposite the base face, the emission tip consisting essentially of semiconductor material, the semiconductor material being doped p-type at least at the apex, wherein the doped p-type level in conjunction with the geometry of the tapered-shaped emission tip shift the work function of the semiconductor material sufficiently close to vacuum level to enable emission of electrons upon absorption of photons.

2. The electron emitter of claim 1, wherein the base face is doped n-type.

3. The electron emitter of claim 1, further comprise a main body formed of doped semiconductor of the same type as the doping of the base face, wherein the emission tip extends from one surface of the main body.

4. The electron emitter of claim 3, further comprising an ohmic contact formed on a second surface of the main body, opposite the one surface.

5. The electron emitter of claim 4, wherein the main body and the emission tip are formed of a monolithic semiconductor material.

6. The electron emitter of claim 4, wherein the main body and the emission tip are formed of a p-type doped semiconductor material.

7. The electron emitter of claim 1, wherein the semiconductor material is selected from materials having electron affinities lower than 1.5 eV in excess of the bandgap.

8. The electron emitter of claim 1, wherein the semiconductor material is selected from one of: doped diamond, gallium nitride (GaN), silicon carbide (SiC) including 4H or 6H allotropic forms, or gallium phosphide (GaP).

9. The electron emitter of claim 1, wherein base face is doped n-type and the apex is doped p-type.

10. The electron emitter of claim 1, wherein emission tip is made of GaN wherein the apex is doped with magnesium (Mg).

11. The electron emitter of claim 1, wherein the emission tip is made of diamond p-type doped with boron.

12. The electron emitter of claim 1, wherein the emission tip is shaped as one of conical or pyramidal shape having from 4 to n facets, where n is below 100.

13. The electron emitter of claim 1, wherein the apex is shaped to have geometry enabling reaching local electric fields above 10 MV/m.

14. The electron emitter of claim 1, wherein the apex has a radius less than 10 microns.

15. An electron source, comprising:
an electron emitter;
a suppressor lens; and
an extractor lens;
wherein the electron emitter comprises a tapered-shaped emission tip having a base face and an apex opposite the base face, the emission tip consisting essentially of semiconductor material, the semiconductor material at the apex being doped p-type, and wherein the base face is doped one of n-type or p-type.

16. The electron source of claim 15, further comprising a laser source positioned to focus a laser beam onto the apex of the emission tip.

17. The electron source of claim 16, wherein the laser source operates at wavelength between 300 and 450 nm.

18. The electron source of claim 15, wherein the apex is shaped to enable reaching local electric fields above 10 MV/m with a 1-20 kV extraction voltage.

19. The electron source of claim 18, wherein the apex has a radius less than 10 microns.

20. The electron source of claim 15, further comprising a main body formed of doped semiconductor of the same polarity as the polarity of the base face, wherein the emission tip extends from one surface of the main body.

21. A multiple-electron beams apparatus, comprising:
a substrate made of semiconducting material doped with a n-type or p-type dopant, the substrate having a sidewall, a first surface and a second surface;
a plurality of emission tips formed on the first surface of the substrate, each emission tip having a tapered-shape with a base attached to the first surface and an apex, each emission tip being doped p-type at the apex;
an ohmic contact formed of the sidewall or on the second surface of the substrate.

22. The apparatus of claim 21, further comprising electrostatic lens layer positioned in close proximity to the plurality of emission tips, and including a plurality of conditioning lenses, each of the conditioning lenses including a suppressor lens and an extractor lens.

23. The apparatus of claim 22, further comprising a laser source generating a laser beam illuminating the plurality of emission tips.

24. The apparatus of claim 23, further comprising at least one of a beam splitter splitting the laser beam into a plurality of laser beams and optical scanner for scanning the laser beam or the plurality of laser beams.
